(19) United States
(12) Patent Application Publication
(10) Pub. No.: US 2015/0214429 A1
(43) Pub. Date: Jul. 30, 2015

(54) METHOD FOR MANUFACTURING ROD-TYPE LIGHT EMITTING DEVICE AND ROD-TYPE LIGHT EMITTING DEVICE

(71) Applicants: TOKYO ELECTRON LIMITED, TOKYO (JP); NATIONAL UNIVERSITY CORPORATION NAGOYA UNIVERSITY, Nagoya-shi (JP)

(72) Inventors: Yoji IIZUKA, Nirasaki City (JP); Yoshihiro KATO, Nirasaki City (JP); Koji NEISHI, Nirasaki City (JP); Hitoshi MIURA, Nirasaki City (JP); Shinya KIKUTA, Nirasaki City (JP); Yusaku KASHIWAGI, Nirasaki City (JP); Hiroshi AMANO, Nagoya-shi (JP); Yoshio HONDA, Nagoya-shi (JP)

(21) Appl. No.: 14/607,723

(22) Filed: Jan. 28, 2015

(30) Foreign Application Priority Data
Jan. 29, 2014 (JP) 2014-014223

(51) Int. Cl. H01L 33/20; H01L 33/06; H01L 33/32; H01L 33/00

(52) U.S. Cl. CPC H01L 33/20; H01L 33/0075; H01L 33/06; H01L 33/32

(57) ABSTRACT

There is provided a method for manufacturing a rod-type light emitting device, which includes: forming a rod having lateral surfaces and an upper surface on a GaN layer of a first conductivity-type, the rod being made of a GaN of the first conductivity-type; selectively growing a high-resistivity layer on the upper surface of the rod; forming a multi-quantum well layer to cover the lateral surfaces and the upper surface of the rod and the high-resistivity layer; and forming a GaN layer of a second conductivity-type to cover the multi-quantum well layer.

### CROSS-REFERENCE TO RELATED APPLICATION

This application claims the benefit of Japanese Patent Application No. 2014-014223, filed on Jan. 29, 2014, in the Japan Patent Office, the disclosure of which is incorporated herein in its entirety by reference.

### TECHNICAL FIELD

Embodiments of the present disclosure relate to a method for manufacturing a rod-type light emitting device and a rod-type light emitting device.

### BACKGROUND

Light emitting devices have been used as a light source for various purposes. In general, as such a light emitting device, and a planar light emitting device are known. However, in recent years, a rod-type light emitting device having a light emitting area larger than that of the planar light emitting device has been developed.

The rod-type light emitting device includes a plurality of rods. Each of the plurality of rods is formed of an n-type GaN. In addition, in the rod-type light emitting device, multi-quantum well layers are formed to cover the respective rods, and p-type GaN layers are formed to cover the respective multi-quantum layers.

In the rod-type light emitting device manufactured as above, light is generated from the multi-quantum well layers formed adjacent to lateral surfaces (i.e., m-planes) of the rod and an upper surface (i.e., c-plane) of the rod.

In this case, in the multi-quantum well layer, portions grown on the lateral surfaces of the rod and a portion grown on the upper surface of the rod have different introduction amounts of indium. In addition, in the multi-quantum well layer, the portions grown on the lateral surfaces of the rod and the portion grown on the upper surface of the rod have different growth rates. As such, in the multi-quantum well layer, a wavelength of light emitted from the portions grown on the lateral surfaces of the rod and a wavelength of light emitted from the portion grown on the upper surface of the rod may be different. As a result, a wavelength spectrum of light generated by the rod-type light emitting device may widen.

### SUMMARY

Some embodiments of the present disclosure provide a rod-type light emitting device capable of generating light having a narrow wavelength spectrum, and a method for manufacturing the light emitting device.

According to one embodiment of the present disclosure, there is provided a method for manufacturing a rod-type light emitting device, which includes: forming a rod having lateral surfaces and an upper surface on a GaN layer of a first conductivity-type, the rod being made of a GaN of the first conductivity-type; selectively growing a high-resistivity layer on the upper surface of the rod; forming a multi-quantum well layer to cover the lateral surfaces and the upper surface of the rod and the high-resistivity layer; and forming a GaN layer of a second conductivity-type to cover the multi-quantum well layer.

According to another embodiment of the present disclosure, there is provided a rod-type light emitting device, including: a GaN layer of a first conductivity-type; a rod having lateral surfaces and an upper surface and formed on the GaN layer, the rod being made of a GaN of the first conductivity-type; a high-resistivity layer selectively grown on an upper surface of the rod; a multi-quantum well layer formed to cover the lateral surfaces and the upper surface of the rod and the high-resistivity layer; and another GaN layer of a second conductivity-type formed to cover the multi-quantum well layer.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view showing a rod-type light emitting device according to an embodiment of the present disclosure.

FIGS. 2 to 7 are views showing products produced by processes of the method for manufacturing a rod-type light emitting device, according to another embodiment of the present disclosure, respectively.

### DETAILED DESCRIPTION

Reference will now be made in detail to various embodiments, examples of which are shown in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

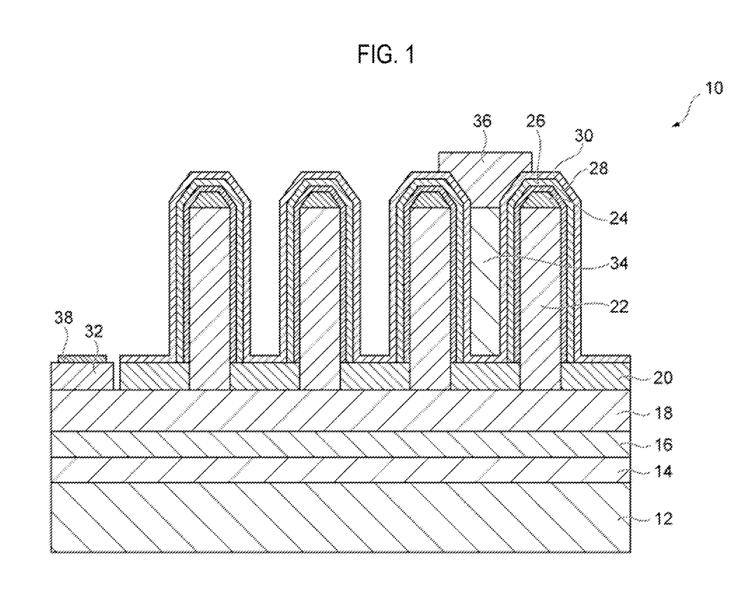

First, a rod-type light emitting device according to one embodiment of the present disclosure will be described. FIG. 1 is a cross-sectional view showing the rod-type light emitting device according to one embodiment of the present disclosure. As shown in FIG. 1, the rod-type light emitting device 10 includes a substrate 12, a first layer 14, a second layer 16, a first conductivity-type GaN layer 18, a mask 20, one or more rods 22, high-resistivity layers 24, multi-quantum well layers 26, second conductivity-type GaN layers 28, a first electrode 30, a second electrode 32, an insulating part 34, a first electrode pad 36, and a second electrode pad 38.

The substrate 12 is a sapphire substrate or a silicon (Si) substrate. The first conductivity-type GaN layer 18 is formed on the substrate 12 with the first layer 14 and the second layer 16 interposed therebetween. The first layer 14 serves as a buffer layer and may be formed of, e.g., an aluminum nitride (AlN). The second layer 16 is, for example, an undoped GaN layer. In some embodiments, when the substrate 12 is a sapphire substrate, the second layer 16 or the first conductivity-type GaN layer 18 may be directly formed on the substrate 12.

In this embodiment, the first conductivity-type GaN layer 18 is an n-type layer. The first conductivity-type GaN layer 18 may contain an impurity (e.g., silicon (Si)) as a dopant. The mask 20 is formed on the first conductivity-type GaN layer 18.

The mask 20 is formed of, for example, SiO₂. The mask 20 has a pattern with a plurality of openings in which the rods 22 are formed. The rods 22, which are made of GaN of the first conductivity-type (n-type), are formed on regions exposed through the openings of the mask 20 in the first conductivity-type GaN layer 18. Each of the rods 22 has a substantially hexagonal column shape when viewed from the top, and includes lateral surfaces and an upper surface. The lateral surfaces of the rod 22 extend in a thickness direction of the first conductivity-type GaN layer 18. Also, the upper surface of the rod 22 extends in a direction crossing the lateral surfaces of the rod 22 and constitutes a top surface of the rod 22. The high-resistivity layer 24 is formed on the upper surface of the rod 22.

The high-resistivity layer 24 is a layer selectively grown from the upper surface of the rod 22. The high-resistivity layer 24 has a high resistance value and serves to prevent a current from flowing through the upper surface of the rod 22 between the rod 22 and the second conductivity-type GaN layer 28 when a current is applied to the rod-type light emitting device 10. The second conductivity-type is p-type. In some embodiments, the high-resistivity layer 24 may be constituted as, e.g., an undoped GaN layer, an Al-added GaN layer, a carbon-added GaN layer or an AlN layer.

Further, in the rod-type light emitting device 10, the multi-quantum well layer 26 is formed to cover the rod 22 and the high-resistivity layer 24. The multi-quantum well layer 26 is formed by alternately stacking a plurality of InGaN layers and a plurality of GaN layers.

The second conductivity-type GaN layer 28 is formed to cover the multi-quantum well layer 26. The second conductivity-type GaN layer 28 may contain an impurity (e.g., magnesium (Mg) or zinc (Zn)) as a dopant. In some embodiments, the second conductivity-type GaN layer 28 may not be directly formed on the multi-quantum well layer 26. As an example, an AlGaN layer of the second conductivity-type may be formed between the multi-quantum well layer 26 and the second conductivity-type GaN layer 28.

The first electrode 30 is formed on the second conductivity-type GaN layer 28 and the mask 20. The first electrode 30 may be, for example, a transparent electrode. Further, the first electrode 30 may be formed of a material such as ITO, ZnO, or InGaZnO₄. In the rod-type light emitting device 10, a partial region of the first conductivity-type GaN layer 18 is exposed. The second electrode 32 is formed on the exposed region of the first conductivity-type GaN layer 18. For example, the second electrode 32 may be constituted as a stacked body obtained by sequentially stacking titanium (Ti), aluminum (Al), titanium (Ti), and gold (Au).

Further, in the rod-type light emitting device 10, the insulating part 34 is formed to bury a gap between the rods 22. For example, the insulating part 34 may be constituted as a transparent insulator. The first electrode pad 36 is formed on the insulating part 34 and on some regions of the first electrode 30. Further, the second electrode pad 38 is formed on the second electrode 32. For example, the first electrode pad 36 and the second electrode pad 38 may be constituted as a stacked body of titanium (Ti) followed by gold (Au), respectively.

Once the current is applied to the rod-type light emitting device 10 through the first electrode pad 36 and first electrode 30, light is generated from the multi-quantum well layer 26. However, since the high-resistivity layer 24 is formed on the upper surface of the rod 22, the application of the current to the upper surface of the rod 22 is suppressed, thus preventing the light from being generated from the multi-quantum well layer 26 positioned on the upper surface of the rod 22. The current is applied to the multi-quantum well layer 26 positioned between the lateral surfaces of the rod 22 and the second conductivity-type GaN layer 28. With this configuration, the rod-type light emitting device 10 can generate light having a narrow wavelength spectrum.

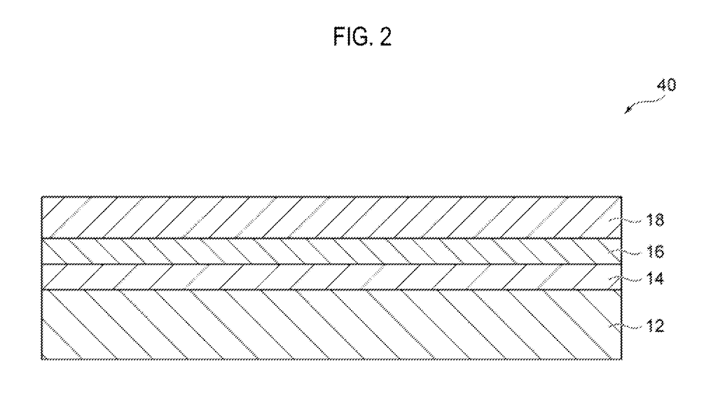

Hereinafter, a method for manufacturing the rod-type light emitting device 10 will be described as another embodiment of the present disclosure. FIGS. 2 to 7 are views showing products produced by processes of the rod-type light emitting device manufacturing method according to another embodiment of the present disclosure, respectively.

As shown in FIG. 2, in the manufacturing method according to another embodiment, the first layer 14 followed by the second layer 16 is grown (or formed) on the substrate 12. The first layer 14 and the second layer 16 may be formed using a growth device, for example, a metal organic chemical vapor deposition (MOCVD) device.

Subsequently, in the manufacturing method according to another embodiment, the first conductivity-type GaN layer 18 is formed on the second layer 16. Similarly, the first conductivity-type GaN layer 18 may be formed using a growth device such as a MOCVD device. In this way, a product 40 as shown in FIG. 2 is produced.

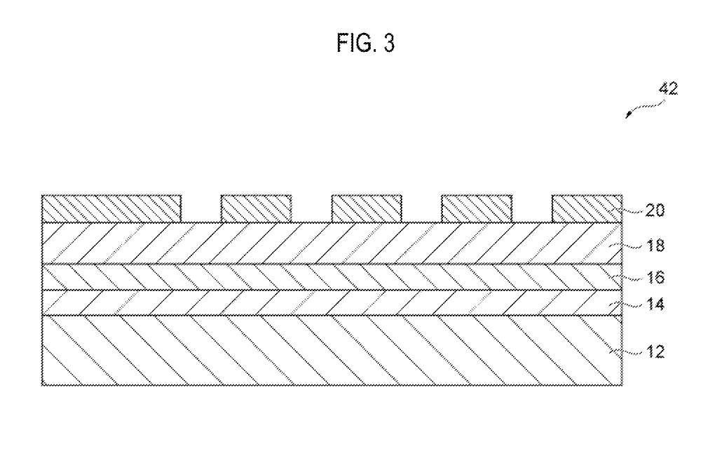

Thereafter, in the manufacturing method according to another embodiment, the mask 20 is formed on the first conductivity-type GaN layer 18. The mask 20 is formed by: forming a mask layer on the first conductivity-type GaN layer 18; forming another mask on the mask layer through photolithography; and etching the mask layer through the another mask. In this way, a product 42 as shown in FIG. 3 is produced.

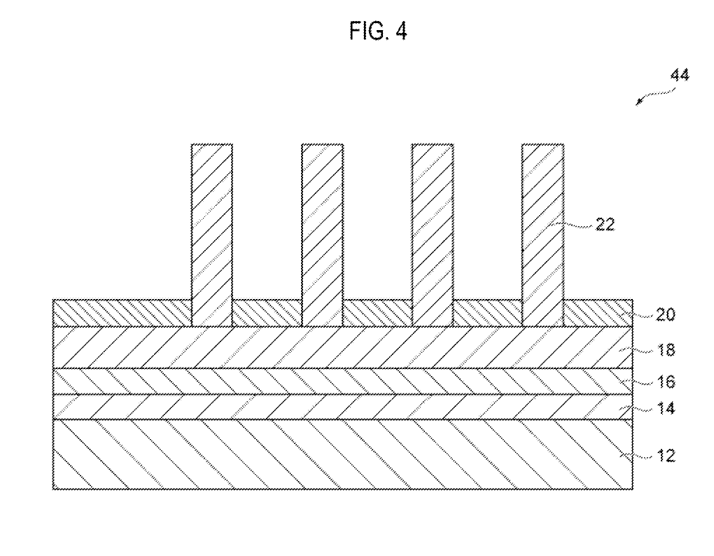

Subsequently, the rods 22 each of which is made of GaN of the first conductivity-type are formed. Similarly, the rods 22 may be formed using the growth device such as the MOCVD device. Specifically, the rods 22 are formed by epitaxial-growing the first conductivity-type GaN on regions exposed through the openings of the mask 20 in the first conductivity-type GaN layer 18. In this way, a product 44 as shown in FIG. 4 is produced.

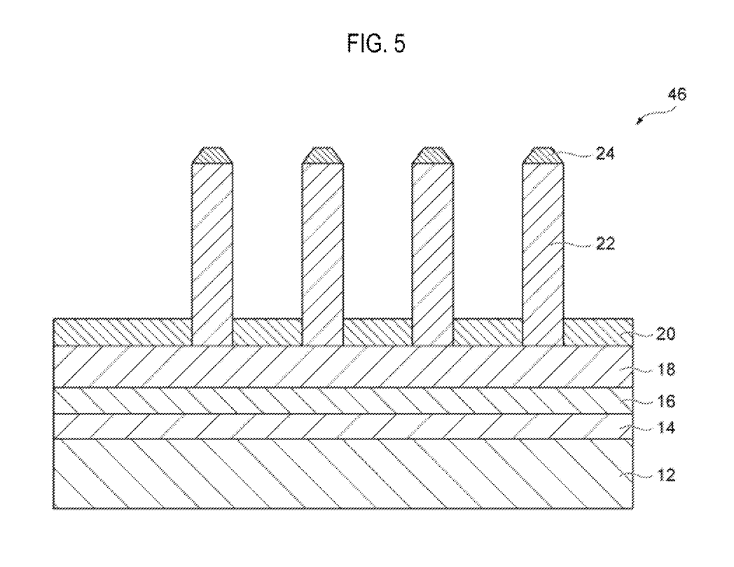

Thereafter, each of the high-resistivity layers 24 is selectively grown on the upper surface of each of the rods 22. The high-resistivity layer 24 may be formed using a growth device such as a MOCVD device. In some embodiments, the high-resistivity layer 24 may be grown, after forming the rods 22, using a single growth device. A rate at which a semiconductor compound of elements from III-V group, which constitutes the high-resistivity layer 24, is grown from the upper surface of the rod 22, is faster than that at the semiconductor compound of elements from III-V group is grown from the lateral surfaces of the rod 22. With this configuration, it is possible to selectively grow the high-resistivity layer 24 from the upper surface of the rod 22. In this way, a product 46 as shown in FIG. 5 is produced.

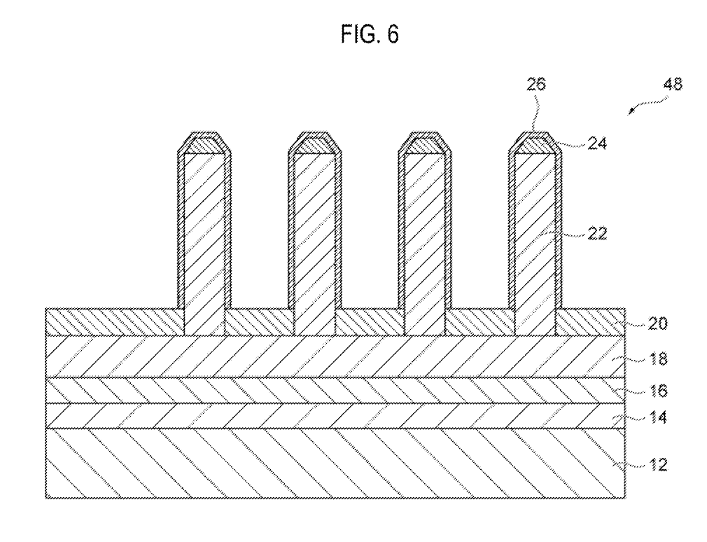

Subsequently, the multi-quantum well layer 26 is formed to cover the rod 22 and the high-resistivity layer 24. Similarly, the multi-quantum well layer 26 may be formed using a growth device such as a MOCVD device. As a result, a product 48 as shown in FIG. 6 is produced.

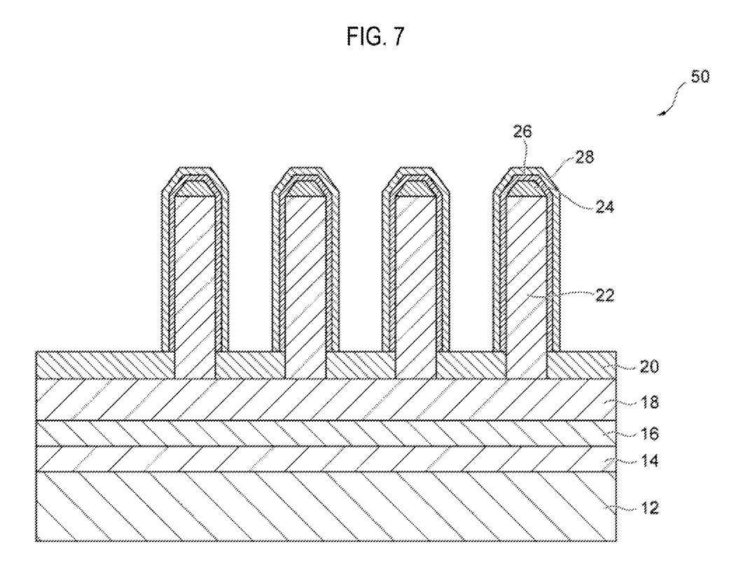

Thereafter, the second conductivity-type GaN layer 28 is formed to cover the multi-quantum quantum well layer 26. Similarly, the second conductivity-type GaN layer 28 may be formed using a growth device such as a MOCVD device. As a result, a product 50 as shown in FIG. 7 is produced. In some embodiments, after the formation of the multi-quantum well layer 26 and before the formation of the second conductivity-type GaN layer 28, an AlGaN layer of the second conductivity-type may be formed along the surface of the multi-quantum well layer 26.

Subsequently, a portion of the surface of the first conductivity-type GaN layer 18 is exposed by etching. As shown in FIG. 1, the second electrode 32 is formed on the exposed portion of the first conductivity-type GaN layer 18. Further, the first electrode 30 is formed on the second conductivity-type GaN layers 28 and the mask 20. The first electrode 30 may be formed by, e.g., a deposition or sputtering process.

Subsequently, the second electrode pad 38 is formed on the second electrode 32, and the first electrode pad 36 is formed on the first electrode 30. Thus, it is possible to manufacture the light emitting device 10 as shown in FIG. 1.

In the manufacturing method configured as above, since the high-resistivity layer 24 is selectively grown on the upper surface of the rod 22. In some embodiments, as a method of growing the high-resistivity layer 24 on the upper surface of the rod 22, an alternative method of: forming a flat surface including the upper surface of the rod 22; forming a layer made of a high-resistivity material on the flat surface; and performing a process such as etching or lift-off to leave the high-resistivity layer only on the upper surface of the rod 22, may be employed. However, according to the manufacturing method of the present disclosure, compared with the alternative method, it is possible to decrease the number of processes, thus preventing damage to the rods 22.

Further, according to the manufacturing method of the above embodiment, it is possible to successively form the rods 22 and the high-resistivity layers 24 using a single growth device. This improves a manufacturing throughput of the rod-type light emitting device 10.

While the present disclosure has described exemplary embodiments, the present disclosure is not limited thereto, but may be modified in a variety of forms. As an example, electrodes of the light emitting device 10 may be formed in certain regions as long as a p-type electrode is electrically connected to a p-type GaN layer and an n-type electrode is electrically connected to an n-type GaN layer. In some embodiments, all of the first layer 14, the second layer 16, the first conductivity-type GaN layer 18, the rods 22, the high-resistivity layers 24, the multi-quantum well layers 26 and the second conductivity-type GaN layer 28 may be formed using a single growth device. The single growth device may include a plurality of growth chambers, each of which is configured to perform the same processes entirely. In some embodiments, the plurality of growth chambers may be respectively responsible for the processing of some layers different to each other so that the processes are entirely completed. Alternatively, some of the plurality of growth chambers may be arranged to be in charge of the processing of some specific layers. Such a configuration, in conjunction with each other, allows the processes to be entirely carried out.

According to the manufacturing method of the present disclosure, a high-resistivity layer is formed on an upper surface of a rod, thus preventing current from being applied to a multi-quantum well layer through the upper surface of the rod. This suppresses light from being emitted from the multi-quantum well layer formed on the upper surface of the rod. Therefore, according to the manufacturing method of the present disclosure, it is possible to provide a rod-type light emitting device capable of generating light having a narrow wavelength spectrum. Further, according to the manufacturing method of the present disclosure, it is possible to selectively growing the high-resistivity layer.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method for manufacturing a rod-type light emitting device, comprising:
forming a rod having lateral surfaces and an upper surface on a GaN layer of a first conductivity-type, the rod being made of a GaN of the first conductivity-type;
selectively growing a high-resistivity layer on the upper surface of the rod;
forming a multi-quantum well layer to cover the lateral surfaces and the upper surface of the rod and the high-resistivity layer; and
forming a GaN layer of a second conductivity-type to cover the multi-quantum well layer.

2. The method of claim 1, wherein forming a rod and selectively growing a high-resistivity layer are sequentially performed using a single growth device.

3. The method of claim 1, wherein the high-resistivity layer is an undoped GaN layer, an Al-added GaN layer, a carbon-added GaN layer or an AlN layer.

4. A rod-type light emitting device, comprising:
a GaN layer of a first conductivity-type;
a rod having lateral surfaces and an upper surface and formed on the GaN layer, the rod being made of a GaN of the first conductivity-type;
a high-resistivity layer selectively grown on an upper surface of the rod;
a multi-quantum well layer formed to cover the lateral surfaces and the upper surface of the rod and the high-resistivity layer; and
another GaN layer of a second conductivity-type formed to cover the multi-quantum well layer.

5. The device of claim 4, wherein the high-resistivity layer is an undoped GaN layer, an Al-added GaN layer, a carbon-added GaN layer or an AlN layer.
